(19) United States
(12) Patent Application Publication
(10) Pub. No.: US 2009/0061617 A1
(43) Pub. Date: Mar. 5, 2009

(54) EDGE BEAD REMOVAL PROCESS WITH ECMP TECHNOLOGY

(76) Inventors: Alain Duboust, Sunnyvale, CA (US); Jose Salas-Vernis, Santa Clara, CA (US); Antoine P. Manens, Sunnyvale, CA (US)

Correspondence Address: PATTERSON & SHERIDAN, LLP - - APPM/TX, 3040 POST OAK BOULEVARD, SUITE 1500, HOUSTON, TX, 77056, US

(21) Appl. No.: 11/849,714

(22) Filed: Sep. 4, 2007

(51) Int. Cl. H01L 21/3063

(52) U.S. Cl. 438/631; 205/642; 438/692; 451/37; 257/E21.216

(57) ABSTRACT

A method and apparatus for the removal of a deposited conductive layer along an edge of a substrate using a power ring configured to electro polish an edge of the substrate are provided. The electro polishing of the substrate edge may occur simultaneously with the electrochemical mechanical processing of a substrate face. In certain embodiments a method of electrochemically polishing a substrate having a conductive material disposed thereon is provided. A substrate is coupled with a carrier head comprising a power ring which surrounds an edge of the substrate, wherein the edge of the substrate includes the conductive material. A polishing pad is contacted with a face of the substrate. A first voltage is applied to the power ring to remove conductive material from the edge of the substrate. A second voltage different from the first voltage is applied to the polishing pad to remove a portion of the conductive material from the face of the substrate.

### BACKGROUND OF THE INVENTION

1. Field of the Invention

Embodiments of the present invention as recited in the claims generally relate to removal of a deposited conductive layer from a substrate. More particularly, embodiments of the invention relate to electro polishing the edge of a substrate during electrochemical mechanical polishing of the face of the substrate.

2. Description of the Related Art

In the fabrication of integrated circuits and other electronic devices, deposition of a conductive layer on a substrate, such as a copper layer used to fill features formed within a dielectric material, results in excess copper deposited on a face of the substrate and a peripheral edge of the substrate that wraps onto the face. The excess copper on the face can cause problems such as shorts in the circuit. Additionally, the excess copper extending onto the edge of the substrate can lead to delamination of the copper layer and other problems even if the edge portion is part of an unusable section of the substrate. Therefore, the excess copper must be removed from both the edge and the face of the substrate prior to subsequent processing of the substrate, which may include the addition and removal of additional layers of conducting, semiconducting, and dielectric materials in order to form multilevel interconnects of the integrated circuit.

Electrochemical Mechanical Processing (ECMP) provides one technique used to remove the excess copper from the face of the substrate surface by electrochemical dissolution while concurrently polishing the substrate with reduced mechanical abrasion as compared to conventional Chemical Mechanical Polishing (CMP) processes. Electrochemical dissolution is performed by applying a bias between a cathode and the substrate surface to remove the copper from the substrate surface into a surrounding electrolyte. The bias may be applied to the substrate surface by a conductive contact disposed on or through a polishing material upon which the substrate is processed. A mechanical component of the polishing process is performed by providing relative motion between the substrate and the polishing material that enhances the removal of the copper from the substrate. Direct contact between the substrate and the polishing material removes a passivation layer protecting the copper, thereby enabling the polishing and planarization via ECMP.

However, ECMP effectively only removes the excess copper on the face of the substrate and not the edge of the substrate since the polishing material does not contact the edge. Therefore, an edge bead removal (EBR) step is currently required between the copper deposition step and the ECMP step. The EBR may occur within the same system used for deposition and includes the additional time consuming process of spinning the substrate as a nozzle directs an etching solution onto the excess copper along the edge of the substrate. The nozzle for the EBR requires adjustments and tuning in order to attempt to selectively direct the etching solution at only the desired edge portion of the substrate. Thus, the additional EBR step in the manufacture of the integrated circuit increases costs by slowing throughput, increasing the overall complexity of the system used for deposition, and requiring use of additional consumable material.

Therefore, there exists a need for an improved method and apparatus for removal of a deposited conductive layer along an edge of a substrate.

### SUMMARY OF THE INVENTION

The present invention as recited in the claims generally relates to methods and apparatus for removal of a deposited conductive layer along the edge of a substrate using a power ring that surrounds the edge of the substrate and is configured to electropolish the edge of the substrate. The electro polishing of the edge of the substrate may occur simultaneously with the electrochemical mechanical polishing of the face of the substrate. In certain embodiments a method of electrochemically polishing a substrate having a conductive material disposed thereon is provided. The substrate is coupled with a carrier head comprising a power ring which surrounds an edge of the substrate, wherein the edge of the substrate includes the conductive material. A polishing pad is contacted with a face of the substrate. A first voltage is applied to the power ring to remove conductive material from an edge of the substrate. A second voltage different from the first voltage is applied to the polishing pad to remove a portion of the exposed conductive layer from the face of the substrate. In certain embodiments the first voltage is greater than the second voltage.

In certain embodiments a method of electrochemically polishing a substrate having a conductive material disposed thereon is provided. A first voltage is supplied to a power ring surrounding an edge of the substrate, wherein the edge of the substrate includes the conductive material, wherein the first voltage is capable of electropolishing the edge of the substrate. A second voltage is supplied to an electrode disposed proximate a face of the substrate. The face of the substrate is electrochemical mechanically polished while the edge of the substrate is simultaneously electro polished.

In certain embodiments an apparatus for processing a substrate is provided. The apparatus comprises a power ring surrounding an edge of the substrate, the power ring at a first voltage potential selected to enable electro polishing of the edge of the substrate, an electrode facing a face of the substrate, the electrode at a second voltage potential selected to enable electrochemical mechanical processing (Ecmp) of the face of the substrate, and at least one power supply adapted to supply the first voltage potential to the power ring and the second voltage potential to the electrode facing a face of the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts a partial sectional view of an exemplary processing station;

FIG. 2 depicts a partial sectional view of the exemplary processing station through two contact assemblies;

FIG. 3 depicts a partial sectional view of an exemplary polishing pad assembly illustrating an exemplary counter electrode configuration;

FIG. 4 depicts an exploded perspective view of an exemplary power ring; and

FIG. 5 depicts an exemplary flow diagram of a method of electrochemically processing a substrate.

To facilitate understanding, identical reference numerals have been used, wherever possible, to designate identical elements that are common to the figures. It is contemplated that elements and/or process steps of one embodiment may be beneficially incorporated in other embodiments without additional recitation.

### DETAILED DESCRIPTION

Embodiments of the invention as recited in the claims generally relate to edge bead removal (EBR) from a substrate during an electropolishing process. The edge bead removal may occur simultaneously during electrochemical mechanical polishing (Ecmp) of the surface of the substrate.

As used herein, the term “electrochemical mechanical polishing” (Ecmp) generally refers to planarizing a substrate by the application of electrochemical activity, mechanical activity, abrading, and chemical activity to remove material from a substrate surface.

As used herein, the term “electro polishing” generally refers to planarizing a substrate by the application of electrochemical activity without abrasion between the surface to be planarized and the polishing pad.

As used herein, the term “substrate” generally refers to any substrate or material surface formed on a substrate upon which film processing is performed, such as silicon wafers used in semiconductor processing. For example, a substrate on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride. Substrates may have various dimensions, such as 200 mm or 300 mm diameter wafers, as well as, rectangular or square panes.

The polishing process may be performed in a process apparatus, such as a platform having one or more polishing stations adapted for electrochemical mechanical polishing processes. The polishing process may be performed using a fully conductive pad and/or a bagel pad. The one or more polishing stations may be adapted to perform conventional chemical mechanical polishing. A platen for performing an electrochemical mechanical polishing process may include a polishing article, a first electrode, and a second electrode. Examples of suitable systems that can be adapted to benefit from the invention include MIRRA®, MIRRA MESA®, REFLEXION®, REFLEXION® LK, and REFLEXION LK Ecmp™ processing systems, all of which are commercially available from Applied Materials, Inc., of Santa Clara, Calif. Other suitable systems from other manufacturers may also be adapted to benefit from the invention. The following apparatus description is illustrative and should not be construed or interpreted as limiting the scope of the invention.

### Apparatus

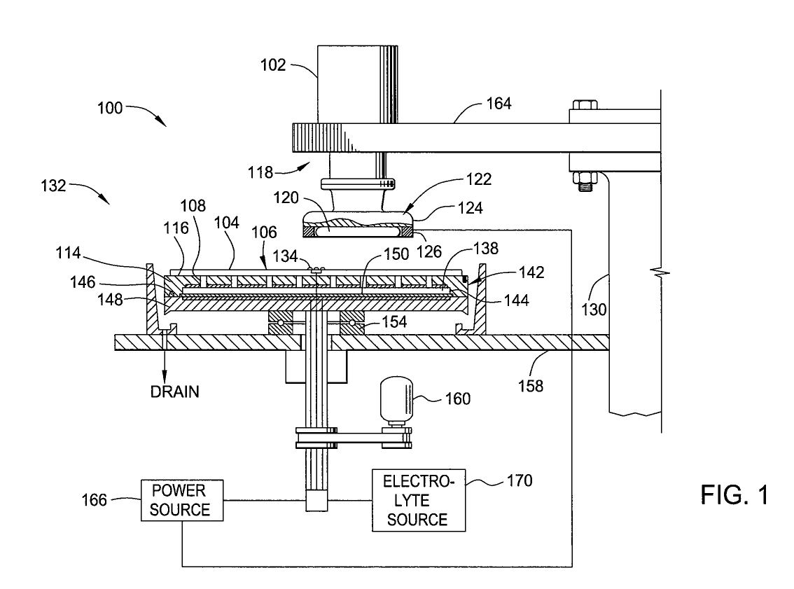

FIG. 1 depicts a partial sectional view of an exemplary processing station 100 employing one embodiment of a polishing pad assembly 106 and a power ring 126 capable of removing an edge bead from a substrate 120. The processing station 100 includes a carrier head assembly 118 adapted to hold the substrate 120 against a platen assembly 142 disposed in an ECMP station 132. Relative motion provided therebetween polishes the substrate 120. The relative motion may be rotational, lateral, or some combination thereof and may be provided by either or both of the carrier head assembly 118 and the platen assembly 142. An arm 164 coupled to a base 130 supports the carrier head assembly 118 over the ECMP station 132.

The carrier head assembly 118 generally includes a drive system 102 coupled to a carrier head 122 for providing at least rotational motion to the carrier head 122. The carrier head 122 additionally may actuate toward the ECMP station 132 such that the substrate 120 retained in the carrier head 122 disposes against a processing surface 104 of the ECMP station 132 during processing. The carrier head 122 includes a housing 124 and a power ring 126 that define a center recess, which retains the substrate 120. In certain embodiments, the power ring 126 comprises an upper portion and a lower portion. In certain embodiments, the power ring 126 comprises a unitary body. The carrier head 122 may be a TITAN HEAD™ or TITAN PROFILER™ wafer carrier manufactured by Applied Materials, Inc., of Santa Clara, Calif.

The ECMP station 132 generally includes the platen assembly 142 having an upper plate 114 and a lower plate 148 rotationally disposed on a base 158. A bearing 154 between the platen assembly 142 and the base 158 facilitates rotation of the platen assembly 142 relative to the base 158. A motor 160 provides the rotational motion to the platen assembly 142. A top surface 116 of the upper plate 114 supports the polishing pad assembly 106 thereon. The lower plate 148 couples to the upper plate 114 by any conventional coupling, such as a plurality of fasteners (not shown). A plurality of locating pins 146 (one is shown in FIG. 1) disposed between the upper and lower plates 114, 148 ensure alignment therebetween. The upper plate 114 and the lower plate 148 may optionally be fabricated from a single, unitary member.

A plenum 138 defined in the platen assembly 142 may be partially formed in at least one of the upper or lower plates 114, 148. In the embodiment depicted in FIG. 1, a recess 144 partially formed in the lower surface of the upper plate 114 defines the plenum 138. At least one aperture 108 formed in the upper plate 114 allows electrolyte provided to the plenum 138 from an electrolyte source 170 to flow through the platen assembly 142 and into contact with the substrate 120 during processing. A cover 150 coupled to the upper plate 114 encloses the recess 144 and partially bounds the plenum 138. Alternatively, a pipe (not shown) may dispense the electrolyte onto the top surface of the polishing pad assembly 106.

At least one contact assembly 134 is disposed on the platen assembly 142 along with the polishing pad assembly 106. The at least one contact assembly 134 extends at least to or beyond the upper surface of the polishing pad assembly 106 and is adapted to electrically couple the substrate 120 with a power source 166. The polishing pad assembly 106 couples with a different terminal of the power source 166 so that an electrical potential may be established between the substrate 120 and the polishing pad assembly 106. Counter electrodes of the polishing pad assembly 106 couple with different terminals of the power source 166 so that an electrical potential may be established between the substrate 120 and the counter electrode. In certain embodiments, the power ring 126 may be coupled with a different terminal of the power source 166. In other words, the contact assembly 134 biases the substrate 120 by electrically coupling the substrate 120 to one terminal of the power source 166 during processing while the substrate 120 is held against the polishing pad assembly 106. The polishing pad assembly 106 couples with another terminal of the power source 166. The electrolyte, which is introduced from the electrolyte source 170 and is disposed on the polishing pad assembly 106, completes an electrical circuit between the substrate 120 and the polishing pad assembly 106 in order to assist in the removal of material from the surface of the substrate 120 and remove material from the edge of the substrate.

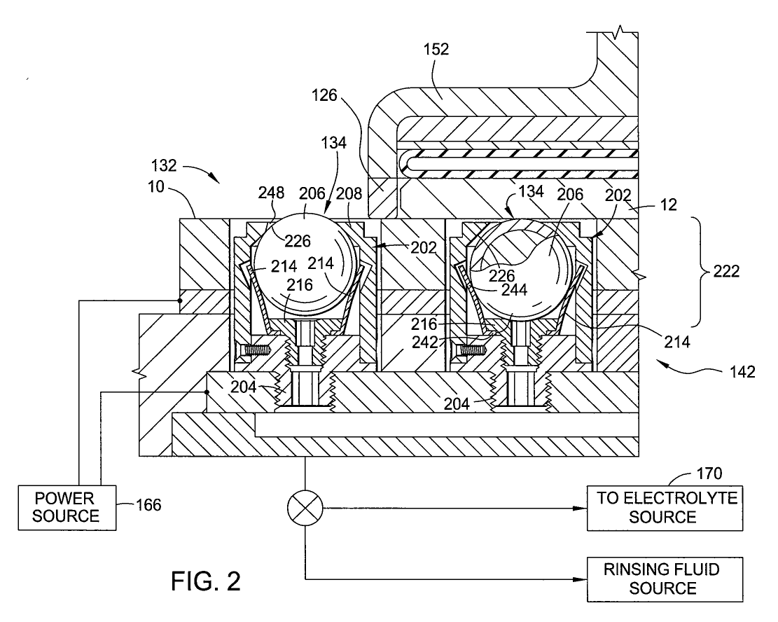

FIG. 2 depicts a partial sectional view of the exemplary processing station through two contact assemblies 134. The platen assembly 142 includes at least one contact assembly 134 projecting therefrom and coupled with the power source 166 that is adapted to bias a surface of the substrate 120 during processing. The contact assemblies 134 may be coupled with the platen assembly 142, part of the polishing article assembly 222, or a separate element. Although two contact assemblies 134 are shown in FIG. 2, any number of contact assemblies may be utilized and may be distributed in any number of configurations relative to the centerline of the platen assembly 142.

The contact assemblies 134 are generally electrically coupled with the power source 166 through the platen assembly 142 and are movable to extend at least partially through respective apertures 108 formed in the polishing article assembly 222. The positions of the contact assemblies 134 may be chosen to have a predetermined configuration across the platen assembly 142. For predefined processes, individual contact assemblies 134 may be repositioned in different apertures 108, while apertures not containing contact assemblies may be plugged with a stopper or filled with a nozzle that allows flow of electrolyte from the plenum 138 to the substrate. One contact assembly that may be adapted to benefit from the invention is described in U.S. Pat. No. 6,884,153, issued Apr. 26, 2005, to Butterfield, et al., and is hereby incorporated by reference in its entirety.

Although the embodiments of the contact assembly 134 described below with respect to FIG. 2 depicts a rolling ball contact, the contact assembly 134 may alternatively comprise a structure or assembly having a conductive upper layer or surface suitable for electrically biasing the substrate 120 during processing. For example, the contact assembly 134 may include an article structure having an upper layer made from a conductive material or a conductive composite (i.e., the conductive elements are dispersed integrally with or comprise the material comprising the upper surface), such as a polymer matrix having conductive particles dispersed therein or a conductive coated fabric, among others. The article structure may include any of the apertures 108 formed therethrough for electrolyte delivery to the upper surface of the article assembly. Other examples of suitable contact assemblies are described in U.S. patent application Ser. No. 10/880,752, filed Jan. 30, 2004, and published as US 2005-0000801, by Hu et al., which is hereby incorporated by reference in its entirety.

In certain embodiments, each of the contact assemblies 134 includes a hollow housing 202, an adapter 204, a ball 206, a contact element 214 and a clamp bushing 216. The ball 206 has a conductive outer surface and is movably disposed in the housing 202. The ball 206 may be disposed in a first position having at least a portion of the ball 206 extending above the processing surface 104 and at least a second position where the ball 206 is substantially flush with the planarizing surface 126. It is also contemplated that the ball 206 may move completely below the processing surface 104. The ball 206 is generally suitable for electrically coupling the substrate 120 to the power source 166. It is contemplated that a plurality of balls 206 for biasing the substrate 120 may be disposed in a single housing.

The power source 166 generally provides a positive electrical bias to the ball 206 during processing. Between planarizing substrates, the power source 166 may optionally apply a negative bias to the ball 206 to minimize attack on the ball 206 by process chemistries.

The housing 202 is configured to provide a conduit for the flow of electrolyte from the source 166 to the substrate 120 during processing. The housing 202 is fabricated from a dielectric material compatible with process chemistries. A seat 226 formed in the housing 202 prevents the ball 206 from passing out of the first end 208 of the housing 202. The seat 226 optionally may include grooves 248 formed therein that allow fluid flow to exit the housing 202 between the ball 206 and seat 226. Maintaining fluid flow past the ball 206 may minimize the propensity of process chemistries to attack the ball 206.

The contact element 214 is coupled between the clamp bushing 216 and the adapter 204. The contact element 214 is generally configured to electrically connect the adapter 204 and ball 206 substantially or completely through the range of ball positions within the housing 202. In certain embodiments, the contact element 214 may be configured as a spring form.

In the embodiment depicted in FIG. 2, the contact element 214 includes an annular base 242 having a plurality of flexures 244 extending therefrom in a polar array. The flexure 244 is generally fabricated from a resilient and conductive material suitable for use with process chemistries. In certain embodiments, the flexure 244 is fabricated from gold plated beryllium copper.

The ball 206 may be solid or hollow and is typically fabricated from a conductive material. For example, the ball 206 may be fabricated from a metal, conductive polymer or a polymeric material filled with conductive material, such as metals, conductive carbon or graphite, among other conductive materials. Alternatively, the ball 206 may be formed from a solid or hollow core that is coated with a conductive material. The core may be non-conductive and at least partially coated with a conductive covering.

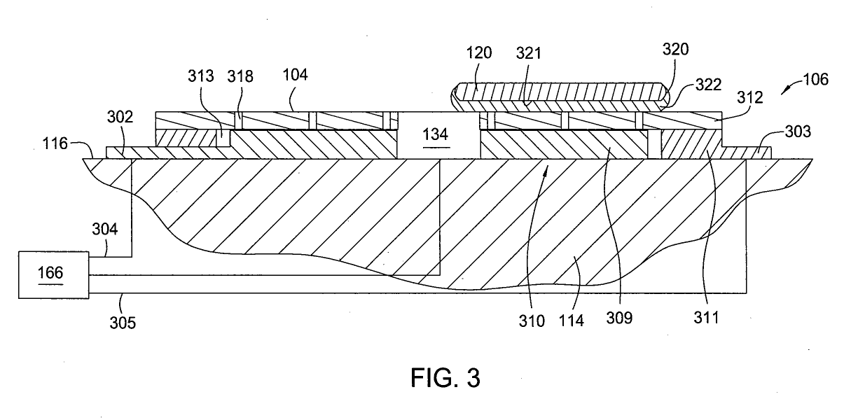

FIG. 3 depicts a partial sectional view of one embodiment of a polishing pad assembly 106 illustrating an exemplary counter electrode configuration. The processing pad assembly 106 includes at least a conductive layer 310 and an upper layer 312 having a processing surface 104. The conductive layer may be tungsten, copper, a layer having both exposed tungsten and copper, aluminum, and the like. In one embodiment, at least one permeable passage 318 disposed at least through the upper layer 312 extends at least to the conductive layer 310 in order to allow the electrolyte to establish a conductive path between the substrate 120 and the conductive layer 310. The use of adhesives, bonding, compression molding, or the like may combine the conductive layer 310 and upper layer 312 of the processing pad assembly 106 into a unitary assembly. Examples of processing pad assemblies that may be adapted to benefit from the invention are described in U.S. Pat. No. 6,991,528, issued Jan. 31, 2006, to Hu et al. (entitled “CONDUCTIVE POLISHING ARTICLE FOR ELECTROCHEMICAL MECHANICAL POLISHING”) and U.S. patent application Ser. No. 10/455,895, filed Jun. 6, 2003, published as US 2004-0020789, by Hu et al. (entitled “CONDUCTIVE POLISHING ARTICLE FOR ELECTROCHEMICAL MECHANICAL POLISHING”), both of which are hereby incorporated by reference in their entireties.

The conductive layer 310 typically includes a corrosion resistant conductive material, such as metals, conductive alloys, metal coated fabrics, conductive polymers, conductive pads, and the like. Conductive metals include Sn, Ni, Cu, Au, and the like. Conductive metals also include a corrosion resistant metal such as Sn, Ni, or Au coated over an active metal such as Cu, Zn, Al, and the like. Conductive alloys include inorganic alloys and metal alloys such as bronze, brass, stainless steel, or palladium-tin alloys, among others. Magnetic attraction, static attraction, vacuum, adhesives, or the like holds the conductive layer 310 on the top surface 116 of the upper plate 114 of the platen assembly 142. Other layers, such as release films, liners, and other adhesive layers, may be disposed between the conductive layer 310 and the upper plate 114 to facilitate ease of handling, insertion, and removal of the processing pad assembly 106 in the processing station 100.

In certain embodiments, the conductive layer 310 includes at least an inner electrode 309 and optionally, an outer electrode 311 that are separated from one another by an air gap 313 or other dielectric spacer. A first terminal 302 facilitates coupling of the inner electrode 309 with the power source 166, and a second terminal 303 facilitates coupling of the outer electrode 311 to the power source 166. For example, stainless steel screws (not shown) respectively secure leads 304, 305 of the power source 166 with the terminals 302, 303. In certain embodiments, the power source 166 supplies a first voltage to the outer electrode 311 and supplies a second voltage to the inner electrode 309, wherein the first voltage and the second voltage are different voltages. The difference in voltages allows for “tuning” of the material removal rates from the substrate. Thus, the conductive layer 310 may comprise at least two independent electrode zones defined by the electrodes 309, 311 and isolated from each other. The conductive layer 310 should also be fabricated of a material compatible with electrolyte chemistries to minimize cross-talk between zones of the electrodes 309, 311. For example, metals stable in the electrolyte chemistries are able to minimize zone cross-talk. In certain embodiments, the conductive layer 310 may comprise a single unitary electrode. In certain embodiments, the conductive layer 310 may comprise additional electrodes providing additional zones that may be utilized to tailor Ecmp performance to obtain good uniformity across the face 221 of the substrate 120. The number of zones may vary from three to five. In certain embodiments where there are five zones a six zone power supply may be used with each of five terminals coupled with each of five zones of the electrode respectively, with the six zone coupled with the power ring 126.

The zone of the inner electrode 309 extends across an area corresponding to a face 321 of the substrate 120 as the substrate 120 and the platen assembly 142 move relative to each other. Proximity of the inner electrode 309 with respect to the face 321 ensures that the zones of the electrode 309 remain proximate the face 321 of the substrate 120, respectively.

In operation, the second voltage supplied to the inner electrode permits ECMP of the face 321 of the substrate 120 due to a combination of electrochemical dissolution and abrasion from direct contact of a copper layer 322 with the processing surface 104. The contact between the copper layer 322 and the processing surface 104 removes a passivation layer from the copper layer 322 and enables polishing and planarization of the face 321. As shown, the copper layer 322 extends onto the edge 320 of the substrate 120 and has not been removed in a separate edge bead removal (EBR) step prior to ECMP of the substrate 120. However, ECMP may not remove the copper layer 322 around the edge 320 since the copper layer 322 around the edge 320 lacks contact with the processing surface 104.

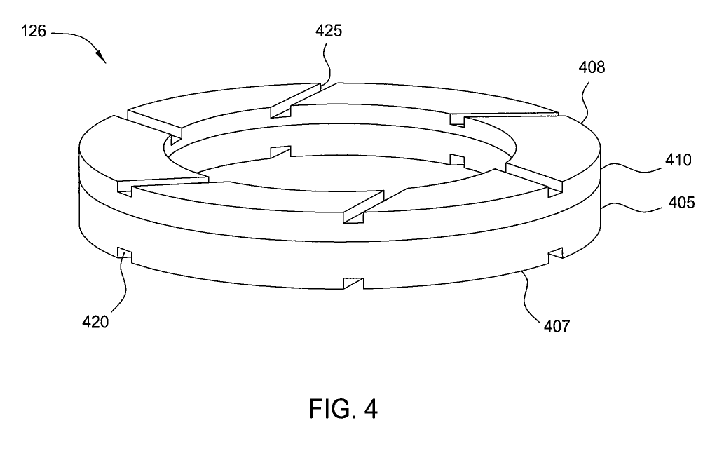

FIG. 4 is an exploded view of an exemplary power ring. The power ring 126 is generally an annular ring that can be secured to the carrier head 122. The power ring 126 holds the substrate 120 within the carrier head 122 during polishing. In certain embodiments, the power ring 126 may comprise an upper portion 410 and a lower portion 405. The lower portion 405 has a lower surface 407 that can be brought into contact with a polishing surface, such as a polishing pad, and an upper surface (not shown). The lower portion 405 of the power ring 126 can be formed of a rigid material, such as a metal, e.g., stainless steel, molybdenum, or aluminum, or a ceramic, e.g., alumina, or other exemplary materials. The lower portion 405 can alternatively be made from plastic that is the same material as the upper portion 410 or a dissimilar material. In certain embodiments, the lower surface 407 of the lower portion 405 has a series of grooves 420.

The upper portion 410 can be formed from a material which is chemically inert in an Ecmp process, such as thermoplastic or polymer material, including polyphenylene sulfide (PPS), polyetheretherketone (PEEK), carbon-filled PEEK, Teflon® polymer filled PEEK, polyethylene terephthalate (PET), polybutylene terephthalate (PBT), polytetrafluoroethylene (PTFE), polybenzimidazole (PBI), polyetherimide (PEI), polyamide-imide (PAI), or a composite material. The upper portion 410 should also be durable and have a low wear rate. In addition, the upper portion 410 should be sufficiently compressible so that contact of the substrate edge against the power ring does not cause the substrate to chip or crack. The upper portion 410 has grooves 425 in the upper surface 408 which are discussed further herein. Examples of contact rings that maybe adapted to benefit from the invention are described in U.S. Pat. No. 7,186,171, issued Mar. 6, 2007, to Oh et al., entitled COMPOSITE RETAINING RING, which is hereby incorporated by reference.

The power ring 126 is coupled with the power source 166. A third terminal (not shown) facilitates coupling of the power ring 126 with the power source 166. For example, stainless steel screws (not shown) respectively secure a lead of the power source 166 with the power ring 126. The power source 166 supplies a voltage to the power ring 126 that can be used to tune the edge profile of the substrate 120. In certain embodiments, the power ring 126 is attached to a separate power supply (not shown).

In a particularly advantageous aspect of the invention, the voltage difference between the power ring 126 and the substrate 120 removes the copper layer 322 along the edge 320 of the substrate 120 during ECMP without requiring the separate EBR step. The power source 166 supplies the first voltage to the power ring 126 such that the voltage difference between the power ring 126 and the substrate 120 is sufficient to remove the copper layer 322 under the action of the bias without requiring any abrasion from the processing surface 104. While the passivation layer protects the copper layer 322 from the voltage difference between the substrate 120 and the inner electrode 309 at the second voltage, the passivation layer does not protect the copper layer 322 from the voltage difference between the substrate 120 and the power ring 126 at the first voltage. Thus, the first voltage supplied to the power ring 126 enables removal or polishing of the copper layer 322 around the edge 320 of the substrate 120 via an electropolishing process. Control of the copper layer 322 removal from the edge 320 of the substrate 120 simply requires adjusting the voltage supplied to the power ring 126.

The power ring 126 selectively removes the copper layer 322 from the edge 320 of the substrate 120 and possibly a small perimeter of the face 321 adjacent the edge 320 since the power ring 126 surrounds the edge 320. Therefore, the power ring 126 only electropolishes the edge 320 while the remainder of the substrate 120 facing or proximate the inner electrode 309 polishes via ECMP. The amount of the copper layer 322 removed around the perimeter of the face 321 depends on the level of the first voltage of the power ring 126 and the proximity of the power ring 126 to the perimeter of the face 321. The electropolishing of the edge 320 may occur simultaneously with ECMP of the face 321 such that removal of the copper layer 322 from the edge 320 does not affect throughput during processing of the substrate 120.

### Methods for Processing a Substrate

Methods are provided for planarizing or polishing a substrate. More particularly, methods are provided for electro polishing the edge of a substrate with a power ring during the electrochemical mechanical polishing of the face of a substrate.

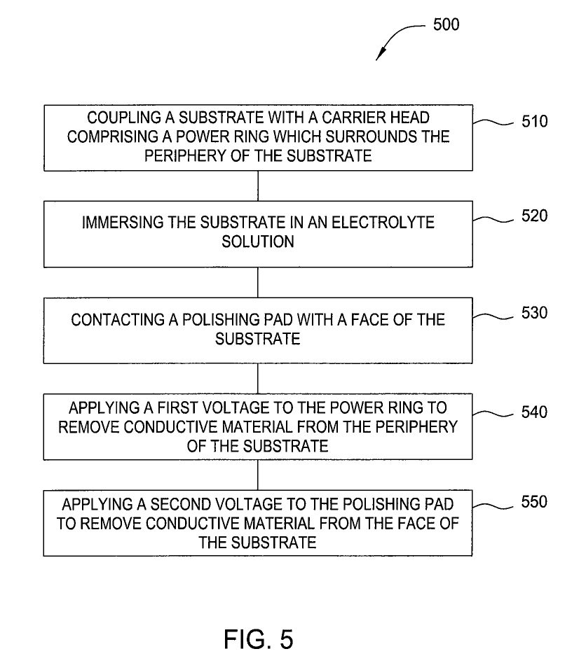

FIG. 5 depicts an exemplary flow diagram of a method 500 of electrochemically processing a substrate having an exposed conductive layer. At step 510 a substrate having an exposed conductive layer is coupled with a carrier head comprising a power ring which surrounds the edge of the substrate. At step 520 the substrate is immersed in an electrolyte solution. At step 530 a polishing pad is contacted with a face of the substrate. At step 540 a first voltage is applied to the power ring to remove conductive material from the edge of the substrate. At step 550 a second voltage is applied to the polishing pad to remove conductive material from the face of the substrate.

At step 510 a substrate 120 having an exposed conductive layer is coupled with a carrier head 122 comprising a power ring 126 which surrounds the edge of the substrate 120. The exposed conductive layer may be tungsten, copper, a layer having both exposed tungsten and copper, aluminum, and the like. In certain embodiments, the carrier head 122 comprises a flexible membrane providing a mounting surface configured to receive the substrate 120 from the backside. The flexible membrane may have one or more chambers connected to a fluid source. When the fluid, such as air, is pumped into the chambers, the volume of the chambers will increase and the flexible membrane will be forced downward. When the fluid is pumped out of the chambers, the volume of the chambers will decrease and the flexible membrane will move upward. To couple the substrate 120 with the carrier head 122, the carrier head 122 generally moves to a position where the flexible membrane of the carrier head 122 is positioned adjacent the back side of the substrate 120. In certain embodiments a seal is formed between the carrier head 122 and the substrate 120. Fluid may then be pumped out of the chamber to create a low pressure pocket between the mounting surface of the flexible membrane and the back side of the substrate 120. This low pressure pocket will vacuum chuck the substrate 120 to the carrier head 122.

At step 520 the substrate 120 coupled with the carrier head 122 and power ring 126 is immersed in an electrolyte solution. The electrolyte is flown into a basin (not shown) and in contact with both the surface of the substrate 120 and the polishing pad assembly 106, while the carrier head 122 places the substrate 120 in contact with the polishing pad assembly 106. When current is applied, the electrolyte establishes an electrically conductive path between the substrate 120 and the polishing pad assembly 106. The electrolyte also establishes an electrically conductive path between the power ring 126 and the substrate 120. In certain embodiments, the electrolyte comprises at least one of sulfuric acid, phosphoric acid, ammonium citrate, and a corrosion inhibitor. Examples of suitable polishing compositions and methods for bulk electrochemical processes are described in U.S. Pat. No. 7,128,825, entitled METHOD AND COMPOSITION FOR POLISHING A SUBSTRATE, issued Oct. 31, 2006 to Liu et al. and U.S. patent application Ser. No. 11/356,352, entitled METHOD AND COMPOSITION FOR POLISHING A SUBSTRATE, filed Feb. 15, 2006, published as U.S. 2006-0169597, both of which are herein incorporated by reference to the extent not inconsistent with the current application.

At step 530 the polishing pad 106 is contacted with a face of the substrate 120. In certain embodiments, the carrier head 122 is lowered toward the polishing pad assembly 106 to place the substrate 120 in contact with the polishing pad assembly 106. In certain embodiments, the substrate 120 contacts the polishing pad assembly 106 after addition of the electrolyte. In certain embodiments, the substrate 120 contacts the polishing pad assembly 106 prior to the addition of the electrolyte. The substrate 120 is urged against the polishing pad assembly 106 with a force of less than about 2 pounds per square inch (psi). In certain embodiments, the surface of the substrate 120 and the polishing pad assembly 106 are contacted at a pressure less than about 2 pounds per square inch (lb/in² or psi) (13.8 kPa). The contact pressure may include a pressure of about 1 psi (6.9 kPa) or less, for example, between about 0.01 psi (69 Pa) and about 1 psi (6.9 kPa), such as between about 0.1 (0.7 kPa) psi and about 0.8 psi (5.5 kPa) or between about 0.1 (0.7 kPa) psi and about 0.5 psi (3.4 kPa). In certain aspects of the process, a pressure of about 0.3 psi (2.1 kPa) or about 0.2 psi (1.4 kPa) may be used during processing.

At step 540, a first voltage is applied to the power ring 126 to remove conductive material from the edge of the substrate 120. The power ring 126 substantially circumscribes an outer perimeter of substrate 120 such that the zone created by the power ring 126 extends at least to an edge 320 of the substrate 120 as the substrate 120 and the platen assembly 142 move relative to each other. Proximity of the power ring 126 with respect to the edge 320 and the inner electrode 309 with respect to the face 321 ensures that the zones of the power ring 126 and the inner electrode 309 extend to the appropriate portions of the substrate 120. During ECMP, the zones of each of the inner electrode 309 and the power ring 126 substantially remain proximate the edge 320 and the face 321 of the substrate 120, respectively.

At step 550, a second voltage is applied to the polishing pad assembly 106 to remove conductive material from the face of the substrate 120. In operation, the second voltage supplied to the inner electrode 309 permits ECMP of the face 321 of the substrate 120 due to a combination of electrochemical dissolution and abrasion from direct contact of a copper layer 322 with the processing surface 104. The contact between the copper layer 322 and the processing surface 104 removes a passivation layer from the copper layer 322 and enables polishing and planarization of the face 321. As shown, the copper layer 322 extends onto the edge 320 of the substrate 120 and has not been removed in a separate edge bead removal (EBR) step prior to ECMP of the substrate 120. However, ECMP may not remove the copper layer 322 around the edge 320 since the copper layer 322 around the edge 320 lacks contact with the processing surface 104. The zone of the inner electrode 309 extends across an area corresponding to a face 321 of the substrate 120 as the substrate 120 and the platen assembly 142 move relative to each other.

The voltage supplied to the inner electrode 309 depends on the working range of the ECMP system and chemistry used therewith in order to obtain the required ECMP performance such as rate, polishing profile, planarization, defects and surface roughness. The power source 166 supplies the first voltage to the power ring 126 at a sufficient voltage to electropolish the edge of the copper layer 322. Therefore, the power source 166 preferably supplies the first voltage to the power ring 126 at preferably between −2 V and −20 V, more preferably between −5 V and −15 V, for example, about −10 V. To permit ECMP of the face 321 of the substrate 120, the power source 166 preferably supplies a bias of approximately zero volts (V) to the substrate 120 and supplies the second voltage to the inner electrode 309 at preferably from zero V to approximately −5 V, most preferably approximately between −2 V and −3 V.

In certain embodiments, the power ring 126 may be used to reduce the copper wear on the copper balls 206 of the platen assembly 142. Significant loss of copper on the copper balls 206 has been observed during the normal operation of the Ecmp process. The copper loss on the copper balls 206 is proportional to both the polishing time and the charge applied to the substrate 120. When the copper balls 206 are in contact with the copper layer 322 of the substrate 120, the copper layer 322 functions as a sacrificial layer. When there is no longer contact between the copper layer 322 and the copper balls 206, dissolution occurs on the copper balls 206. With no bias on the power ring 126, the copper balls 206 are at a more negative potential than the inner electrode 309 which results in electrochemical dissolution of the copper film on the copper balls 206. As a result, the lifetime of the copper balls 206 is significantly reduced. By applying a bias to the power ring 126, the copper dissolution on the copper balls 206 can be greatly reduced. Since the power ring 126 is at a more positive bias than the copper balls 206 and because the power ring 126 is in very close proximity to the copper balls 206, it can significantly reduce the copper dissolution of the copper balls 206. Increasing the lifetime of the copper balls 126 increases the consumable lifetime of the Ecmp system.

It has been advantageously shown that application of the proper voltage to the power ring provides a clean EBR on the Ecmp platen on substrates with full coverage. Since the EBR process may be performed during the Ecmp polishing process, the existing EBR step which is performed in an ECP system may be eliminated. The current EBR process which is performed on the ECP system is an expensive process that decreases system throughput while also requiring the use of additional chemicals. On the other hand, performing the EBR process on the Ecmp platen is an in-situ process which has no impact on the substrate throughput and does not require additional chemistry or hardware setup.

While the foregoing is directed to embodiments of the present invention, other and further embodiments of the invention may be devised without departing from the basic scope thereof, and the scope thereof is determined by the claims that follow.

1. A method of electrochemically polishing a substrate having a conductive material disposed thereon, comprising:
coupling the substrate with a carrier head comprising a power ring which surrounds an edge of the substrate, wherein the edge of the substrate includes the conductive material;
contacting a polishing pad with a face of the substrate;
applying a first voltage to the power ring to remove the conductive material from the edge of the substrate; and
applying a second voltage to the polishing pad to remove a portion of the conductive material from the face of the substrate.

2. The method of claim 1, wherein a potential of the second voltage is higher than a potential of the first voltage.

3. The method of claim 1, wherein the first voltage and the second voltage are selected such that removal of the conductive material from the edge of the substrate occurs at a faster rate than the removal of the conductive material from the face of the substrate.

4. The method of claim 1, wherein the first voltage is between −4 volts to −20 volts and the second voltage is between 0 volts and −5 volts.

5. The method of claim 1, wherein the applying a first voltage to the power ring to remove conductive material from an edge of the substrate comprises removing an edge bead from the edge of the substrate.

6. The method of claim 1, wherein a voltage difference between the substrate and the power ring is between −4 and −20 volts.

7. The method of claim 1, wherein a voltage difference between the substrate and the polishing pad is between 0 and −5 volts.

8. The method of claim 1, wherein the polishing pad is a fully conductive pad.

9. The method of claim 1, wherein the power ring comprises:
a lower portion comprising a polymer material; and
an upper portion comprising stainless steel.

10. A method of electrochemically polishing a substrate having a conductive material disposed thereon, comprising:
supplying a first voltage to a power ring surrounding an edge of the substrate, wherein the edge of the substrate includes the conductive material, wherein the first voltage is capable of electropolishing the edge of the substrate
supplying a second voltage to an electrode disposed proximate a face of the substrate; and
simultaneously electrochemical mechanical polishing (Ecmp) the face of the substrate and electropolishing the edge of the substrate.

11. The method of claim 10, further comprising adjusting the first voltage to control electropolishing of the edge of the substrate.

12. The method of claim 10, wherein the first voltage is between −4 volts and −20 volts.

13. The method of claim 10, wherein the second voltage is between 0 volts and −5 volts.

14. The method of claim 10, wherein the Ecmp includes rotating a polishing surface that is in contact with the substrate.

15. The method of claim 10, wherein the Ecmp includes moving the substrate relative to a polishing surface in contact with the substrate.

16. The method of claim 15, wherein the electropolishing includes removing the conductive material from a portion of the substrate without contact between the polishing surface and the portion of the substrate

17. An apparatus for processing a substrate, comprising:
a power ring surrounding an edge of the substrate, the power ring at a first voltage potential selected to enable electro polishing of the edge of the substrate;
an electrode facing a face of the substrate, the electrode at a second voltage potential selected to enable electrochemical mechanical processing (Ecmp) of the face of the substrate; and
at least one power supply adapted to supply the first voltage potential to the power ring and the second voltage potential to the electrode facing a face of the substrate.

18. The apparatus of claim 17, wherein the power ring is coupled with a carrier head configured to hold the substrate.

19. The apparatus of claim 17, wherein the power ring comprises:
a lower portion comprising a polymer material; and
an upper portion comprising stainless steel.

20. The apparatus of claim 17 further comprising a platen assembly having a polishing surface for contacting the substrate.
